(19) United States
(12) Patent Application Publication
(10) Pub. No.: US 2017/0218273 A1
(43) Pub. Date: Aug. 3, 2017

(54) FLAME-RETARDANT EPOXY RESIN, METHOD FOR PREPARING SAME, AND FLAME-RETARDANT EPOXY RESIN COMPOSITION CONTAINING SAME

(71) Applicant: KOLON INDUSTRIES, INC., Gwacheon-si, Gyeonggi-do (KR)

(72) Inventors: Sung Kyu KANG, Yongin-si (KR); Guang Chun HUANG, Yongin-si (KR)

(73) Assignee: KOLON INDUSTRIES, INC., Gwacheon-si, Gyeonggi-do (KR)

(21) Appl. No.: 15/514,676

(22) PCT Filed: Sep. 30, 2015
(86) PCT No.: PCT/KR2015/010305

§ 371 Date: Mar. 27, 2017

(30) Foreign Application Priority Data
Sep. 30, 2014 (KR) 10-2014-0131352
Sep. 25, 2015 (KR) 10-2015-0136859
Sep. 30, 2015 (KR) 10-2015-0138234

(51) Int. Cl. C09K 21/14; C08F 8/40; H05K 1/03; C09K 21/12

(52) U.S. Cl. CPC C09K 21/14; C09K 21/12; C08F 8/40; H05K 1/0326

(57) ABSTRACT

This invention relates to a flame-retardant epoxy resin, to a method of preparing the same, and to a flame-retardant epoxy resin composition including the same, and more specifically to a flame-retardant epoxy resin, which satisfies properties while improving flame retardancy by increasing the phosphorus content, to a method of preparing the same, and to a flame-retardant epoxy resin composition including the same.

### CROSS REFERENCE TO RELATED APPLICATIONS

This application is a National Stage of International Application No. PCT/KR2015/010305 filed Sep. 30, 2015, claiming priority based on Korean Patent Application Nos. 10-2014-0131352 filed Sep. 30, 2014, 10-2015-0136859 filed Sep. 25, 2015 and 10-2015-0138234 filed Sep. 30, 2015 the contents of all of which are incorporated herein by reference in their entirety.

### TECHNICAL FIELD

The present invention relates to a flame-retardant epoxy resin, a method of preparing the same, and a flame-retardant epoxy resin composition including the same.

### BACKGROUND ART

As a flame retardant for use in conventional flammable polymer materials, a halogen-based flame retardant, which is superior in terms of flame retardancy and economic benefits, has mainly been utilized. In particular, a bromine-based compound having excellent flame retardancy is employed in most common resins, and in order to improve the flame retardancy of a resin that is difficult to impart with flame retardancy, a bromine-based flame retardant is used together with a flame-retardant enhancer or assistant such as an antimony-based flame retardant including antimony trioxide or the like. However, the bromine-based flame retardant generates a toxic gas such as HBr in the event of a fire and thus asphyxiation may occur, and also, there is a concern of creating dioxin as a strong carcinogen upon incineration. Furthermore, since an antimony-based flame retardant, which is used together with the bromine-based flame retardant, is intrinsically carcinogenic, the use thereof is being gradually regulated worldwide, with Europe in the lead.

Accordingly, thorough research into non-halogen flame-retardant compounds is ongoing these days, and a variety of environmentally friendly flame-retardant compounds are being developed. Examples of the non-halogen flame-retardant compounds include phosphorus-, nitrogen compound-, silicon-, and boron-based flame retardants, metal oxides, and metal hydroxides. The promising flame-retardant compound, which may replace the halogen-based flame retardant, is exemplified by a phosphorus-based compound or a nitrogen-based compound.

Particularly useful as a phosphorus-based compound is 9,10-dihydro-9-oxa-10-phosphaphenanthrene-10-oxide (hereinafter abbreviated as “DOPO”). DOPO may be used as an additive but is able to produce a phosphorus-based modified epoxy resin through the reaction with an epoxy resin and thus to impart flame retardancy when used as a main component of the epoxy resin composition.

The reason why DOPO is mainly used is that it has considerable P content, as high as 14.5%, and has a structure in which the one-side direction thereof is opened, thus easily exhibiting flame retardancy. Also, the preparation of a phosphorus-based modified epoxy resin is easy due to high reactivity with an epoxide group.

Although the conventional phosphorus-based modified epoxy resin using DOPO may ensure flame retardancy, limitations are imposed on increasing P content. The properties may deteriorate with an increase in P content. Therefore, the development of an epoxy resin, which directly participates in the reaction to thus improve properties while flame retardancy is ensured by increasing P content, is urgently required.

### DISCLOSURE

### Technical Problem

The present invention is intended to provide a flame-retardant epoxy resin having improved flame retardancy and satisfying heat resistance, moisture absorption and adhesion by increasing P content, a method of preparing the same, and a flame-retardant epoxy resin composition including the same.

### Technical Solution

A first preferable embodiment of the present invention provides a flame-retardant epoxy resin including a compound represented by Chemical Formula 1 below.

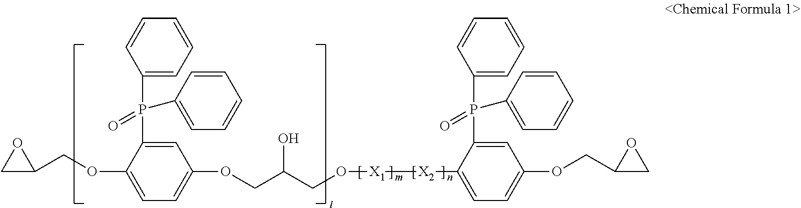

(wherein X₁ is a compound represented by Chemical Formulas 2 to 11 below, X₂ is a compound represented by Chemical Formula 12 below, 1 is 1 to 10, m is 0 to 10, and n is an integer of 1 to 10.)

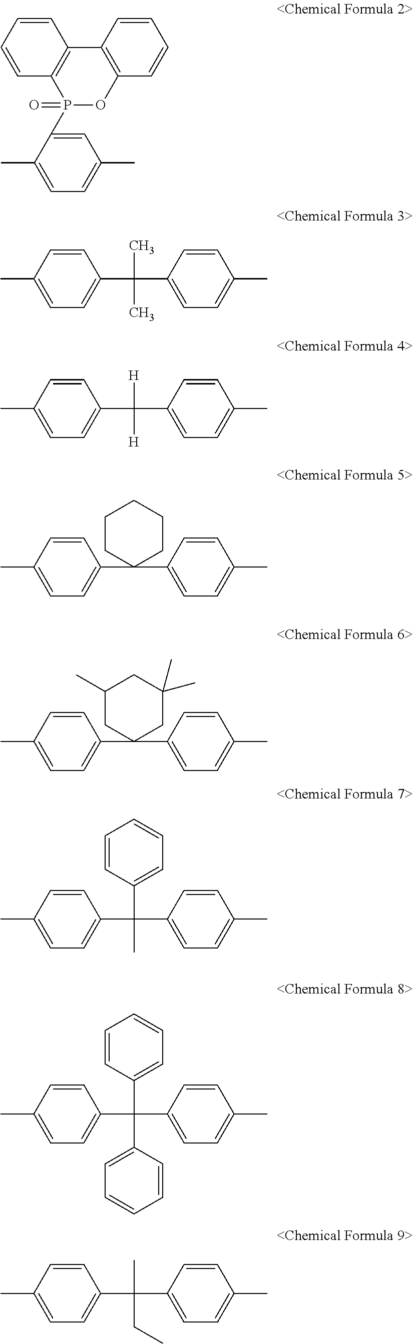

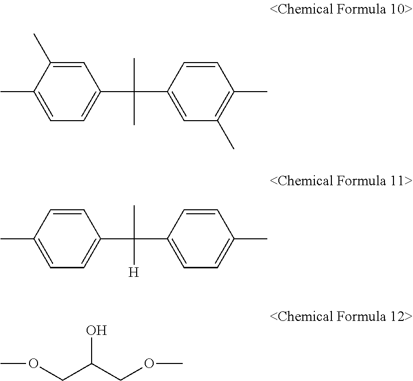

The compound represented by Chemical Formula 1 may have P content of 6 to 8 mass %.

The compound represented by Chemical Formula 1 may have a glass transition temperature of 150 to 190° C.

The compound represented by Chemical Formula 1 may have a weight average molecular weight of 500 to 1500 g/mol.

The compound represented by Chemical Formula 1 may have an epoxy equivalent weight of 350 to 500 g/eq.

A second preferable embodiment of the present invention provides a method of preparing a flame-retardant epoxy resin, comprising: (S1) preparing an intermediate compound by reacting a hydroquinone-based compound containing a phosphorus (P) atom with a halohydrin-based compound; and (S2) reacting the intermediate compound with any one or a mixture of two or more selected from among a phosphorus-based compound and a bisphenol-based compound.

The hydroquinone-based compound containing the phosphorus (P) atom in (S1) may be added at a molar ratio of 1/6 to 1/2 relative to the halohydrin-based compound.

After the reacting the hydroquinone-based compound containing the phosphorus (P) atom with the halohydrin-based compound, a separation process for removing an aqueous salt layer and degassing process for removing the unreacted halohydrin-based compound and water at 100 to 200° C. is performed under a pressure of 100 to 760 torr.

Before the degassing process, the hydroquinone-based compound containing the phosphorus (P) atom and the halohydrin-based compound may be primarily aged for 2 to 24 hr while being maintained at a temperature of 50 to 80° C., and may then be secondarily aged for 10 min to 4 hr while being maintained at a temperature of 50 to 100° C. under a reduced pressure of 100 to 760 torr.

After the degassing process, the removal of a halogen ions using a basic catalyst and neutralization with an acid may be performed.

In (S1), the hydroquinone-based compound containing the phosphorus (P) atom may be diphenylphosphinyl hydroquinone.

In (S1), the halohydrin-based compound may be selected from among epichlorohydrin, epiiodohydrin, epibromohydrin, methyl ethyl bromohydrin and methyl ethyl iodohydrin.

In (S2), 100 parts by weight of the intermediate compound and 0.1 to 100 parts by weight of the any one or mixture of two or more selected from among the phosphorus-based compound and the bisphenol-based compound may be reacted.

In (S2), a catalyst comprising a phenyl-based compound may be added in an amount of 0.01 to 5 parts by weight based on 100 parts by weight of the any one or mixture of two or more selected from among the phosphorus-based compound and the bisphenol-based compound.

In (S2), the phosphorus-based compound may be selected from among 10-(2′,5′-dihydroxyphenyl)-9,10-dihydro-9-oxa-10-phosphaphenanthrene-10-oxide (DOPO-HQ) and 2-(6-oxido-6H-dibenz(c,e)(1,2)oxaphsophorin-6-yl)-1,4-naphthalenediol (DOPO-NQ).

In (S2), the bisphenol-based compound may be selected from among bisphenol A, bisphenol F, bisphenol Z, bisphenol-TMC, bisphenol AP, bisphenol BP, bisphenol B, bisphenol C and bisphenol E.

In (S2), the phenyl-based compound as the catalyst may be selected from among ethyltriphenylphosphonium iodide (ETPPI), 2-methylimidazole (2MI), 2-ethyl-4-methyl imidazole (2E4MZ) and 2-phenylimidazole (2PI).

A third preferable embodiment of the present invention provides a flame-retardant epoxy resin composition comprising a compound represented by Chemical Formula 1 below, a curing agent and a curing promoter.

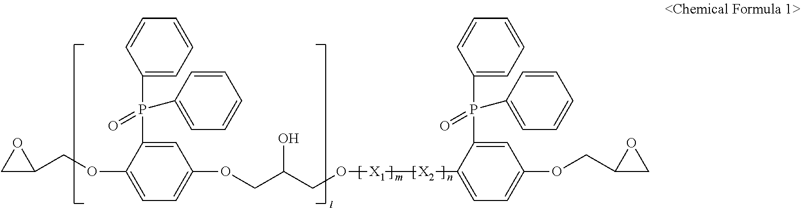

(wherein X₁ is a compound represented by Chemical Formulas 2 to 11 below, X₂ is a compound represented by Chemical Formula 12 below, 1 is 1 to 10, m is 0 to 10, and n is an integer of 1 to 10.)

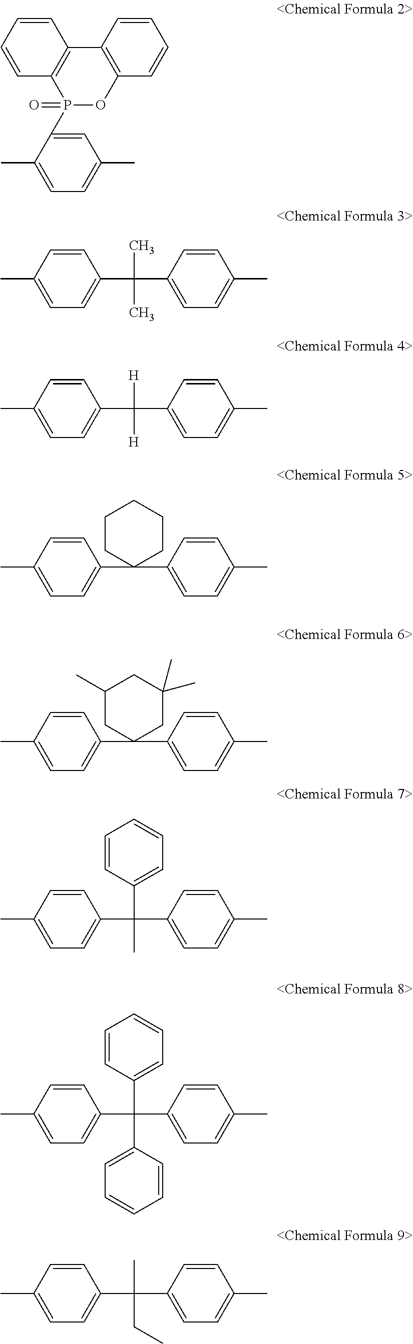

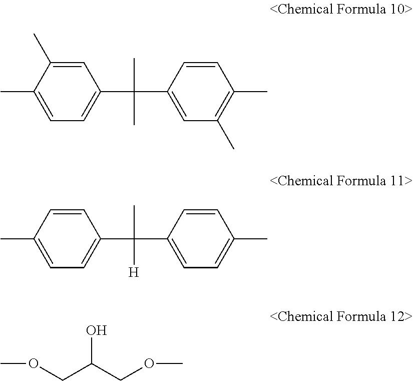

The flame-retardant epoxy resin composition may include 100 parts by weight of the compound represented by Chemical Formula 1, 0.1 to 50 parts by weight of the curing agent and 0.0001 to 0.05 parts by weight of the curing promoter.

The compound represented by Chemical Formula 1 may be prepared using the aforementioned method.

### Advantageous Effects

According to the present invention, a flame-retardant epoxy resin having improved flame retardancy and satisfying heat resistance, moisture absorption and adhesion by increasing P content, a method of preparing the same, and a flame-retardant epoxy resin composition including the same can be provided.

### DESCRIPTION OF DRAWINGS

FIG. 1 is an IR graph showing a compound represented by Chemical Formula 1 in Example 1 according to the present invention; and

FIG. 2 is an IR graph showing a compound represented by Chemical Formula 1 in Example 2 according to the present invention.

### BEST MODE

Hereinafter, a detailed description will be given of the present invention.

The present invention addresses a flame-retardant epoxy resin including a compound represented by Chemical Formula 1 below.

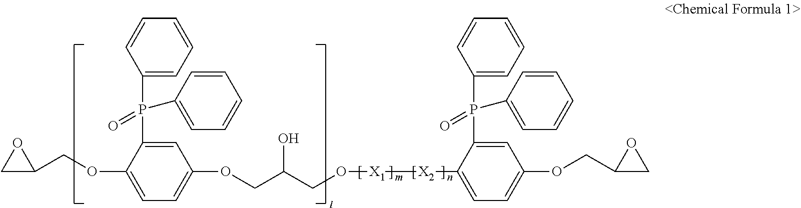

(wherein X₁ is a compound represented by Chemical Formulas 2 to 11 below, X₂ is a compound represented by Chemical Formula 12 below, 1 is 1 to 10, m is 0 to 10, and n is an integer of 1 to 10.)

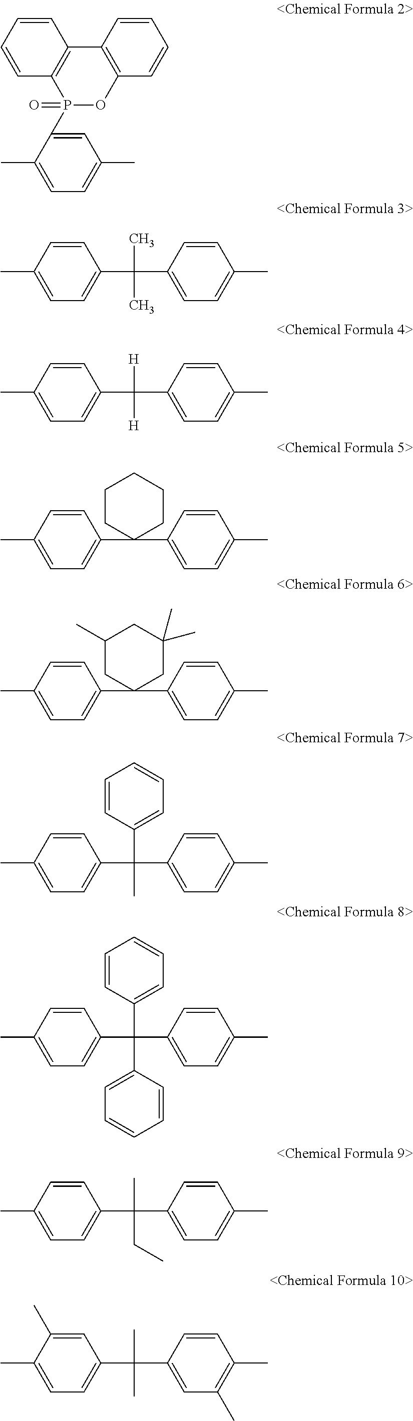

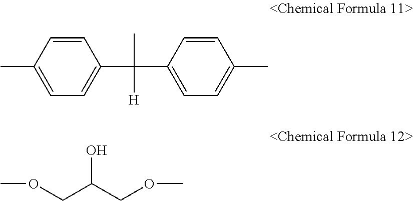

In Chemical Formula 1, if each of 1, m and n exceeds 10, the weight average molecular weight becomes too large, thus increasing the viscosity and deteriorating workability. On the other hand, if each of 1 and n is less than 1, the weight average molecular weight is excessively decreased, and compatibility with the solvent may deteriorate, thus lowering the workability.

In Chemical Formula 1, when X₁ is any one of Chemical Formulas 2 to 11, the number of benzene rings may increase and thus heat resistance may be improved.

In Chemical Formula 1, when X₂ is Chemical Formula 12, the number of —OH groups may increase and thus adhesion may be improved. The compound represented by Chemical Formula 1 may contain P content as high as 6 to 8 mass %. Accordingly, the degree of freedom of the other components of the flame-retardant resin composition may increase. When a composition including a flame-retardant epoxy resin compound is typically prepared, the composition has to include other components able to exhibit various properties of the composition, in addition to the flame-retardant epoxy resin compound. Here, in the case where the flame-retardant epoxy resin compound itself contains P in a small amount, the amount of the flame-retardant epoxy resin compound should be increased to raise the P content in the composition, and thus the amounts of other components are decreased, making it impossible to exhibit the properties of the composition.

Since the compound represented by Chemical Formula 1 according to the present invention has P content as high as 6 to 8 mass %, when the composition including the flame-retardant epoxy resin compound is prepared, the compound represented by Chemical Formula 1 corresponding to the flame-retardant epoxy resin compound may be added in a small amount, and large amounts of other components able to manifest various properties of the composition may be added, ultimately exhibiting desired properties of the composition.

The compound represented by Chemical Formula 1 has a glass transition temperature of 150 to 190° C. Given the above glass transition temperature range, superior heat resistance may result.

The compound represented by Chemical Formula 1 has a weight average molecular weight of 500 to 1500 g/mol. Given the above weight average molecular weight range, compatibility with the solvent may increase and viscosity may decrease, thus attaining good applicability.

The compound represented by Chemical Formula 1 has an epoxy equivalent weight of 350 to 500 g/eq. Given the above epoxy equivalent weight range, high P content and good reactivity with the curing agent may result.

The compound represented by Chemical Formula 1 may be prepared through the steps of (S1) preparing an intermediate compound by reacting a hydroquinone-based compound containing a P atom with a halohydrin-based compound; and (S2) reacting the intermediate compound with any one or a mixture of two or more selected from among a phosphorus-based compound and a bisphenol-based compound.

To begin with, the hydroquinone-based compound containing the P atom is reacted with the halohydrin-based compound, thus preparing the intermediate compound (S1).

The hydroquinone-based compound containing the P atom is added at a molar ratio of 1/6 to 1/2 relative to the halohydrin-based compound. When the hydroquinone-based compound containing the P atom and the halohydrin-based compound are reacted at the above molar ratio, the reaction may be uniformly carried out.

During the reaction of the hydroquinone-based compound containing the P atom and the halohydrin-based compound, a reaction catalyst such as sodium hydroxide or potassium hydroxide may be added, and the use of sodium hydroxide having a concentration of 30 to 60% is preferable in terms of preparing a desired resin, minimizing the production of byproducts and obtaining a desired reaction rate. The amount thereof preferably falls in the range of 10 to 100 parts by weight based on 100 parts by weight of the hydroquinone-based compound containing the P atom. If the amount of the reaction catalyst is less than 10 parts by weight, the epoxy ring is not sufficiently formed, and the above epoxy equivalent weight is not satisfied. On the other hand, if the amount thereof exceeds 100 parts by weight, gelling may occur due to over-reaction.

Here, the hydroquinone-based compound containing the P atom and the halohydrin-based compound are reacted while being heated to 50 to 80° C. After the reaction process, primary aging for 2 to 24 hr while the temperature is maintained at 50 to 80° C. is performed, followed by secondary aging for 10 min to 4 hr while the temperature is maintained at 50 to 100° C. under a pressure of 100 to 760 torr.

According to the present invention, the uniform structure of the flame-retardant epoxy resin compound may be effectively obtained through the primary and secondary aging processes. When the primary and secondary aging processes are performed within the above temperature and time ranges, a uniform structure may result.

During the primary and secondary aging processes, a solvent may be used, and examples thereof may include isopropyl alcohol, methyl ethyl ketone, methyl isobutyl ketone, toluene, and xylene, and the amount thereof is preferably 20 to 80 parts by weight based on 100 parts by weight of the hydroquinone-based compound containing the P atom.

Subsequently, after the reaction of the hydroquinone-based compound containing the P atom and the halohydrin-based compound, a separation process for removal of an aqueous salt layer and degassing process for removal of unreacted halohydrin-based compound and water at 100 to 200° C. is preferably implemented under a pressure of 100 to 760 torr.

After the degassing process, a halogen ion is removed using a basic catalyst, and neutralization with an acid is performed. Specifically, after the degassing process, the solvent is added at 120 to 180° C. in an amount of 10 to 80 parts by weight based on 100 parts by weight of the hydroquinone-based compound containing the P atom, and then the basic catalyst is added and dissolved in an amount of 10 to 100 parts by weight based on 100 parts by weight of the hydroquinone-based compound containing the P atom, followed by the removal of halogen ions and neutralization with an acid. The solvent may include isopropyl alcohol, methyl ethyl ketone, methyl isobutyl ketone, toluene, and xylene, and the acid may include phosphoric acid, sulfuric acid, hydrochloric acid, and carboxylic acid, and the kinds thereof are not limited.

The hydroquinone-based compound containing the P atom is diphenylphosphinyl hydroquinone.

The halohydrin-based compound is selected from among epichlorohydrin, epiiodohydrin, epibromohydrin, methyl ethyl bromohydrin, and methyl ethyl iodohydrin.

The flame-retardant epoxy resin according to the present invention includes the hydroquinone-based compound containing the P atom, thereby enabling the preparation of an epoxy resin having high P content while maintaining the properties thereof. Specifically, a conventional P-based epoxy resin resulting from reacting DOPO with an epoxy resin is theoretically able to increase the P content up to 7.8 mass %. However, the properties may be deteriorated in an amount corresponding thereto. Accordingly, with the goal of solving such problems, the epoxy resin is prepared in the present invention by using the hydroquinone-based compound containing the P atom. The hydroquinone-based compound containing the P atom, for example, diphenylphosphinyl hydroquinone, has a P content of 9.99 mass %, which is lower than 14.5 mass %, which is the P content of DOPO, but has two —OH groups. Thereby, in the present invention, —OH of the hydroquinone-based compound containing the P atom is reacted with the halohydrin-based compound, thus preparing a novel epoxy resin having high P content that satisfies the properties required thereof while increasing P content, unlike the conventional preparation of a P-based epoxy resin through reaction of DOPO and an epoxy resin.

The intermediate compound prepared in (S1) is reacted with any one or a mixture of two or more selected from among a phosphorus-based compound and a bisphenol-based compound, thus preparing a compound represented by Chemical Formula 1 (S2).

The intermediate compound and the any one or mixture of two or more selected from among the phosphorus-based compound and the bisphenol-based compound are used such that 100 parts by weight of the intermediate compound and 0.1 to 100 parts by weight of the any one or mixture of two or more selected from among the phosphorus-based compound and the bisphenol-based compound are reacted. When the amounts of the intermediate compound and the any one or mixture of two or more selected from among the phosphorus-based compound and the bisphenol-based compound fall within the above ranges, an appropriate reaction viscosity may result, thus making it easy to perform the processing.

(S2) is preferably performed at a temperature of 100 to 160° C. for 1 to 8 hr in order to ensure stable processing.

During the reaction, the solvent may include methoxypropan-2-ol, 2-methoxyethanol, acetone, and dioxane, and the amount thereof is preferably 10 to 50 parts by weight based on 100 parts by weight of the intermediate compound.

The phosphorus-based compound is selected from among 10-(2′,5′-Dihydroxyphenyl)-9,10-dihydro-9-oxa-10-phosphaphenanthrene-10-oxide (DOPO-HQ) and 2-(6-oxido-6H-dibenz(c,e)(1,2)oxaphsophorin-6-yl)-1,4-naphthalenediol (DOPO-NQ).

The bisphenol-based compound is selected from among bisphenol A, bisphenol F, bisphenol Z, bisphenol-TMC, bisphenol AP, bisphenol BP, bisphenol B, bisphenol C and bisphenol E.

In (S2), the catalyst as phenyl-based compound including the phenyl-based compound may be added in an amount of 0.01 to 5 parts by weight based on 100 parts by weight of the any one or mixture of two or more selected from among the phosphorus-based compound and the bisphenol-based compound in order to increase the reaction rate.

The phenyl-based compound is selected from among ethyltriphenylphosphonium iodide (ETPPI), 2-methylimidazole (2MI), 2-ethyl-4-methyl imidazole (2E4MZ) and 2-phenylimidazole (2PI).

The flame-retardant epoxy resin composition according to the present invention includes the compound represented by Chemical Formula 1, prepared by the above method, a curing agent and a curing promoter. The flame-retardant epoxy resin composition includes 100 parts by weight of the compound represented by Chemical Formula 1, 0.1 to 50 parts by weight of the curing agent and 0.0001 to 0.05 parts by weight of the curing promoter.

When the curing agent is contained in the above range, an appropriate curing rate may result.

Any curing agent that is typically useful in the art to which the present invention belongs may be used, and examples thereof may include dicyandiamide, phenol novolac, and 4-aminophenyl sulfone. If the amount of the curing promoter is less than the above range, a curing reaction may not occur well. On the other hand, if it is higher than the above range, over-reaction may occur.

Any curing promoter that is typically useful in the art to which the present invention belongs may be used, and examples thereof may include ethyltriphenylphosphonium iodide (ETPPI), 2-methylimidazole (2MI), 2-ethyl-4-methyl imidazole (2E4MZ), and ETPPI.

### MODE FOR INVENTION

A better understanding of the present invention may be obtained through the following examples, which are set forth to illustrate, but are not construed as limiting the scope of the present invention, as is apparent to those skilled in the art.

### Example 1

In a 10 L multi-neck flask, diphenylphosphinyl hydroquinone (DPPQ) (1500 g, 1 mol) and epichlorohydrin (4470 g, 5 mol) were added to isopropyl alcohol (1970 g), mixed well, and heated with stirring to 60±5° C. 81 g of a 50% sodium hydroxide aqueous solution was added all at once while the temperature was maintained at 60±5° C., after which the resulting mixture was aged for 4 hr while the temperature was maintained at 60±5° C. After the completion of aging, while the temperature was maintained at 60±5° C. under a reduced pressure of 250±10 torr, 810 g of a 50% sodium hydroxide aqueous solution was added over 2 hr and then the resulting mixture was aged for 30 min. Subsequently, 714 g of water was added, the salt layer at the lower position was removed using a separatory funnel, and the temperature was increased to 150° C., and thus unreacted epichlorohydrin and water were removed. After the completion of the stripping process, the resulting compound was cooled to 70±10° C., after which 4990 g of methyl isobutyl ketone (MIBK) was added. Subsequently, a 20% sodium hydroxide aqueous solution was used two to three times, thus removing chlorine ions from the organic layer of the resin dissolved in MIBK, and neutralization with phosphoric acid, filtration, and MIBK stripping were performed, thereby obtaining about 1840 g of a dark intermediate compound as an epoxy product.

Subsequently, 200 g of the intermediate compound prepared above and 29.2 g of 10-(2′,5′-dihydroxyphenyl)-9,10-dihydro-9oxa-10-phosphaphenanthrene-10-oxide (DOPO-HQ) were placed in a 2 L multi-neck flask and heated with stirring to 110±10° C. 0.15 g of a 10% ethyltriphenylphosphonium iodide (ETPPI) solution dissolved in methanol was added at 110±10° C., and the resulting mixture was heated to 157±2° C. The reaction time when the temperature reached 157±2° C. was taken as the initial time, and the reaction was carried out at 157±2° C. until the target equivalent weight appeared, determined by sampling every hour. After the appearance of the target equivalent weight, the temperature was decreased to 120±10° C., and propylene glycol monomethyl ether (PGME) was then added, thus obtaining about 470 g of a compound represented by Chemical Formula 1 below as a final material. The compound represented by Chemical Formula 1 had a P content of 7.7 mass %, a glass transition temperature of 165.1° C., a weight average molecular weight of 1013 g/mol, and an epoxy equivalent weight of 343.1 g/eq.

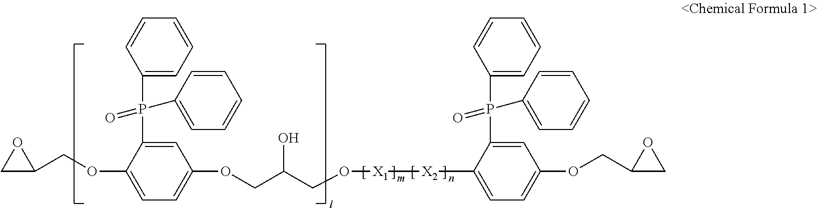

(wherein X₁ is a compound represented by Chemical Formula 2 below, X₂ is a compound represented by Chemical Formula 12 below, 1 is 1 to 2, m is 1 to 2, and n is an integer of 1 to 2.)

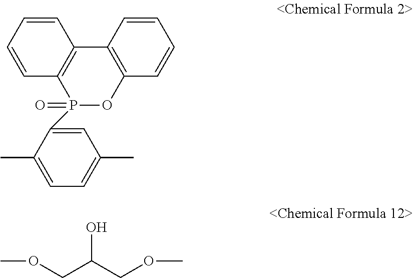

### Example 2

200 g of the intermediate compound prepared in the same manner as in Example 1 and 22.7 g of bisphenol-A (BPA) were placed in a 2 L multi-neck flask and heated with stirring to 110±10° C. 0.15 g of a 10% ETPPI solution dissolved in methanol was added at 110±10° C. and the resulting mixture was heated to 157±2° C. The reaction time when the temperature reached 157±2° C. was taken as the initial time, and the reaction was carried out at 157±2° C. until the epoxy equivalent weight reached 340 g/eq, determined by sampling every hour. After the epoxy equivalent weight reached 340 g/eq, the temperature was decreased to 120±10° C. and PGME was then added, thus obtaining about 470 g of a compound represented by Chemical Formula 1 below as a final material. The compound represented by Chemical Formula 1 had a P content of 6.7 mass %, a glass transition temperature of 170.1° C., a weight average molecular weight of 893 g/mol, and an epoxy equivalent weight of 370.5 g/eq.

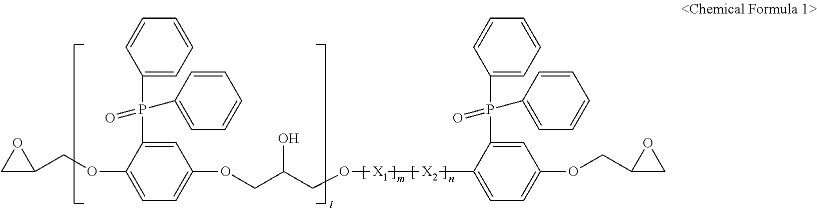

(wherein X₁ is a compound represented by Chemical Formula 3 below, X₂ is a compound represented by Chemical Formula 12 below, 1 is 1 to 2, m is 1 to 2, and n is an integer of 1 to 2.)

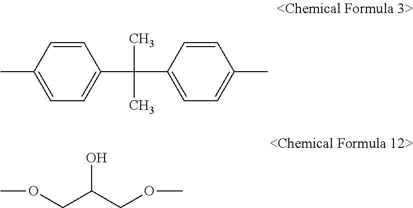

### Example 3

200 g of the intermediate compound prepared in the same manner as in Example 1 and 10 g of bisphenol F were placed in a 2 L multi-neck flask and heated with stirring to 110±10° C. 0.15 g of a 10% ETPPI solution dissolved in methanol was added at 110±10° C. and the resulting mixture was heated to 157±2° C. The reaction time when the temperature reached 157±2° C. was taken as the initial time, and the reaction was carried out at 157±2° C. until the epoxy equivalent weight reached 320 g/eq, determined by sampling every hour. After the epoxy equivalent weight reached 320 g/eq, the temperature was decreased to 120±10° C., and PGME was then added, thus obtaining about 205 g of a compound represented by Chemical Formula 1 below as a final material. The compound represented by Chemical Formula 1 had a P content of 7.0 mass %, a glass transition temperature of 168.7° C., a weight average molecular weight of 843 g/mol, and an epoxy equivalent weight of 322.1 g/eq.

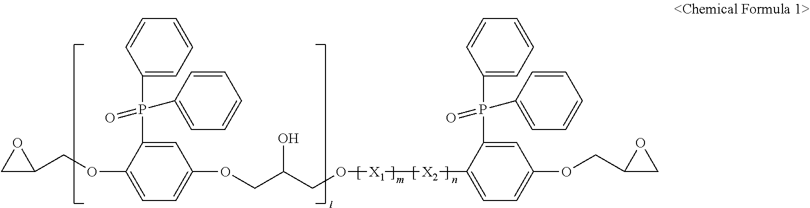

(wherein X₁ is a compound represented by Chemical Formula 4 below, X₂ is a compound represented by Chemical Formula 12 below, 1 is 1 to 2, m is 1 to 2, and n is an integer of 1 to 2.)

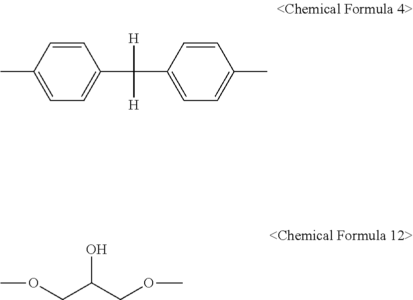

### Example 4

200 g of the intermediate compound prepared in the same manner as in Example 1 and 40 g of bisphenol Z were placed in a 2 L multi-neck flask and heated with stirring to 110±10° C. 0.15 g of a 10% ETPPI solution dissolved in methanol was added at 110±10° C. and the resulting mixture was heated to 157±2° C. The reaction time when the temperature reached 157±2° C. was taken as the initial time, and the reaction was carried out at 157±2° C. until the epoxy equivalent weight reached 340 g/eq, determined by sampling every hour. After the epoxy equivalent weight reached 340 g/eq, the temperature was decreased to 120±10° C. and PGME was then added, thus obtaining about 240 g of a compound represented by Chemical Formula 1 below as a final material. The compound represented by Chemical Formula 1 had a P content of 6.6 mass %, a glass transition temperature of 169.1° C., a weight average molecular weight of 943 g/mol, and an epoxy equivalent weight of 345.5 g/eq.

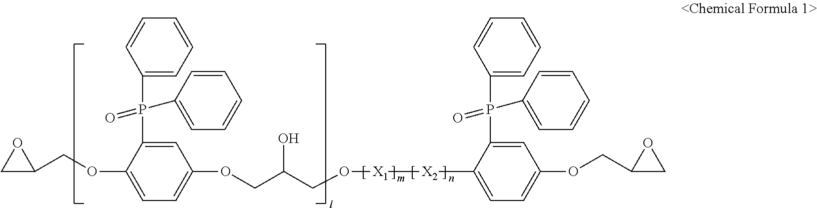

(wherein X₁ is a compound represented by Chemical Formula 5 below, X₂ is a compound represented by Chemical Formula 12 below, 1 is 1 to 2, m is 1 to 2, and n is an integer of 1 to 2.)

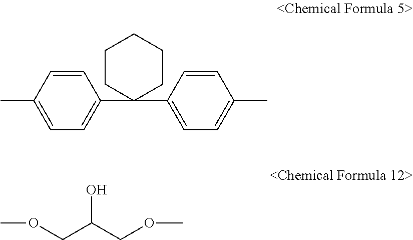

### Example 5

200 g of the intermediate compound prepared in the same manner as in Example 1 and 5 g of bisphenol TMC were placed in a 2 L multi-neck flask and heated with stirring to 110±10° C. 0.15 g of a 10% ETPPI solution dissolved in methanol was added at 110±10° C. and the resulting mixture was heated to 157±2° C. The reaction time when the temperature reached 157±2° C. was taken as the initial time, and the reaction was carried out at 157±2° C. until the epoxy equivalent weight reached 380 g/eq, determined by sampling every hour. After the epoxy equivalent weight reached 380 g/eq, the temperature was decreased to 120±10° C., and PGME was then added, thus obtaining about 205 g of a compound represented by Chemical Formula 1 below as a final material. The compound represented by Chemical Formula 1 had a P content of 6.5 mass %, a glass transition temperature of 163.5° C., a weight average molecular weight of 987 g/mol, and an epoxy equivalent weight of 390.1 g/eq.

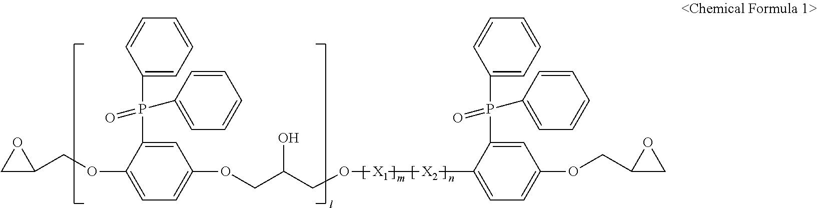

(wherein X₁ is a compound represented by Chemical Formula 6 below, X₂ is a compound represented by Chemical Formula 12 below, 1 is 1 to 2, m is 1 to 2, and n is an integer of 1 to 2.)

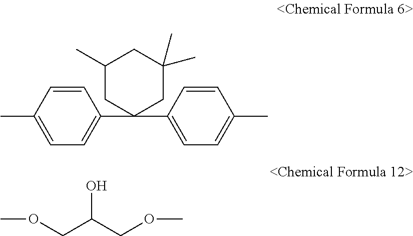

### Example 6

200 g of the intermediate compound prepared in the same manner as in Example 1 and 50 g of bisphenol AP were placed in a 2 L multi-neck flask and heated with stirring to 110±10° C. 0.15 g of a 10% ETPPI solution dissolved in methanol was added at 110±10° C. and the resulting mixture was heated to 157±2° C. The reaction time when the temperature reached 157±2° C. was taken as the initial time, and the reaction was carried out at 157±2° C. until the target epoxy equivalent weight reached 390 g/eq, determined by sampling every hour. After the target epoxy equivalent weight reached 390 g/eq, the temperature was decreased to 120±10° C. and PGME was then added, thus obtaining about 250 g of a compound represented by Chemical Formula 1 below as a final material. The compound represented by Chemical Formula 1 had a P content of 6.5 mass %, a glass transition temperature of 175.4° C., a weight average molecular weight of 1027 g/mol, and an epoxy equivalent weight of 400 g/eq.

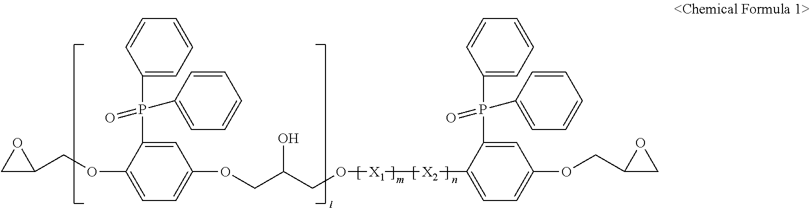

(wherein X₁ is a compound represented by Chemical Formula 7 below, X₂ is a compound represented by Chemical Formula 12 below, 1 is 1 to 2, m is 1 to 2, and n is an integer of 1 to 2.)

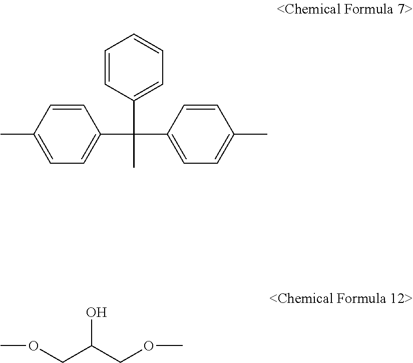

### Example 7

200 g of the intermediate compound prepared in the same manner as in Example 1 and 50 g of bisphenol BP were placed in a 2 L multi-neck flask and heated with stirring to 110±10° C. 0.15 g of a 10% ETPPI solution dissolved in methanol was added at 110±10° C. and the resulting mixture was heated to 157±2° C. The reaction time when the temperature reached 157±2° C. was taken as the initial time, and the reaction was carried out at 157±2° C. until the target epoxy equivalent weight reached 410 g/eq, determined by sampling every hour. After the target epoxy equivalent weight reached the above value, the temperature was decreased to 120±10° C., and PGME was then added, thus obtaining about 250 g of a compound represented by Chemical Formula 1 below as a final material. The compound represented by Chemical Formula 1 had a P content of 6.4 mass %, a glass transition temperature of 177.1° C., a weight average molecular weight of 1127 g/mol, and an epoxy equivalent weight of 420 g/eq.

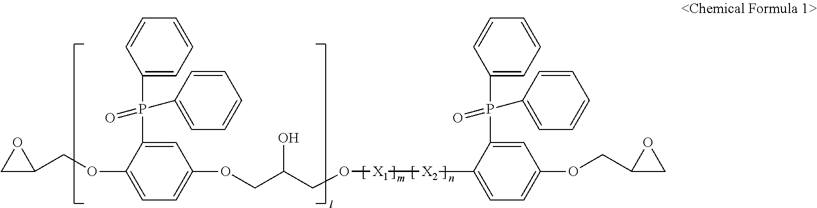

(wherein X₁ is a compound represented by Chemical Formula 8 below, X₂ is a compound represented by Chemical Formula 12 below, 1 is 1 to 2, m is 1 to 2, and n is an integer of 1 to 2.)

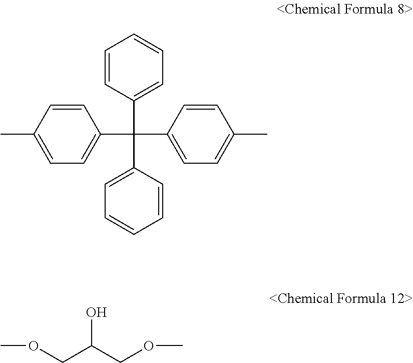

### Example 8

200 g of the intermediate compound prepared in the same manner as in Example 1 and 50 g of bisphenol B were placed in a 2 L multi-neck flask and heated with stirring to 110±10° C. 0.15 g of a 10% ETPPI solution dissolved in methanol was added at 110±10° C. and the resulting mixture was heated to 157±2° C. The reaction time when the temperature reached 157±2° C. was taken as the initial time, and the reaction was carried out at 157±2° C. until the target epoxy equivalent weight reached 380 g/eq, determined by sampling every hour. After the target epoxy equivalent weight reached the above value, the temperature was decreased to 120±10° C., and PGME was then added, thus obtaining about 250 g of a compound represented by Chemical Formula 1 below as a final material. The compound represented by Chemical Formula 1 had a P content of 6.7 mass %, a glass transition temperature of 168.3° C., a weight average molecular weight of 827 g/mol, and an epoxy equivalent weight of 388 g/eq.

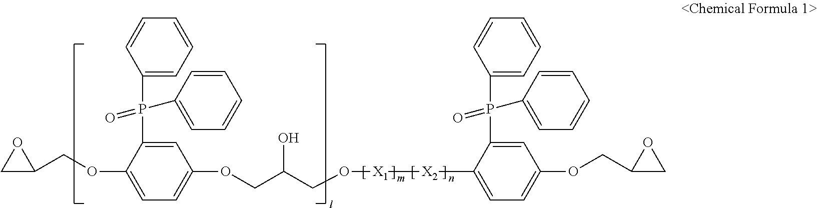

(wherein X₁ is a compound represented by Chemical Formula 9 below, X₂ is a compound represented by Chemical Formula 12 below, 1 is 1 to 2, m is 1 to 2, and n is an integer of 1 to 2.)

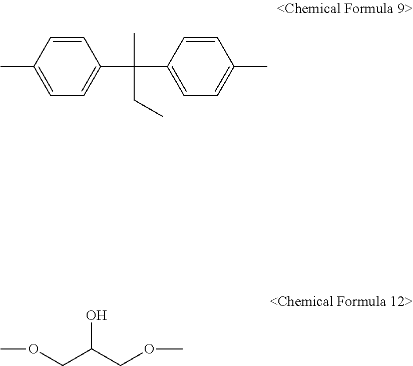

### Example 9

200 g of the intermediate compound prepared in the same manner as in Example 1 and 50 g of bisphenol C were placed in a 2 L multi-neck flask and heated with stirring to 110±10° C. 0.15 g of a 10% ETPPI solution dissolved in methanol was added at 110±10° C. and the resulting mixture was heated to 157±2° C. The reaction time when the temperature reached 157±2° C. was taken as the initial time, and the reaction was carried out at 157±2° C. until the target epoxy equivalent weight reached 370 g/eq, determined by sampling every hour. After the target epoxy equivalent weight reached the above value, the temperature was decreased to 120±10° C. and PGME was then added, thus obtaining about 250 g of a compound represented by Chemical Formula 1 below as a final material. The compound represented by Chemical Formula 1 had a P content of 6.6 mass %, a glass transition temperature of 167.4° C., a weight average molecular weight of 727 g/mol, and an epoxy equivalent weight of 373 g/eq.

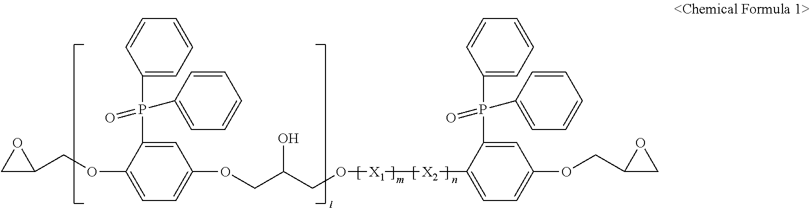

(wherein X₁ is a compound represented by Chemical Formula 10 below, X₂ is a compound represented by Chemical Formula 12 below, 1 is 1 to 2, m is 1 to 2, and n is an integer of 1 to 2.)

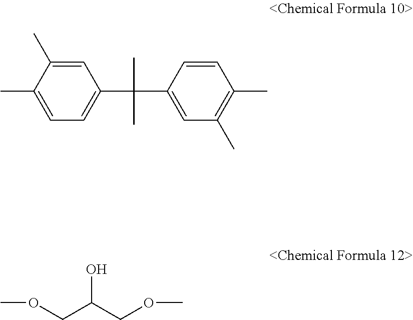

### Example 10

200 g of the intermediate compound prepared in the same manner as in Example 1 and 50 g of bisphenol E were placed in a 2 L multi-neck flask and heated with stirring to 110±10° C. 0.15 g of a 10% ETPPI solution dissolved in methanol was added at 110±10° C. and the resulting mixture was heated to 157±2° C. The reaction time when the temperature reached 157±2° C. was taken as the initial time, and the reaction was carried out at 157±2° C. until the target epoxy equivalent weight reached 360 g/eq, determined by sampling every hour. After the target epoxy equivalent weight reached the above value, the temperature was decreased to 120±10° C. and PGME was then added, thus obtaining about 250 g of a compound represented by Chemical Formula 1 below as a final material. The compound represented by Chemical Formula 1 had a P content of 6.8 mass %, a glass transition temperature of 166.1° C., a weight average molecular weight of 627 g/mol, and an epoxy equivalent weight of 364 g/eq.

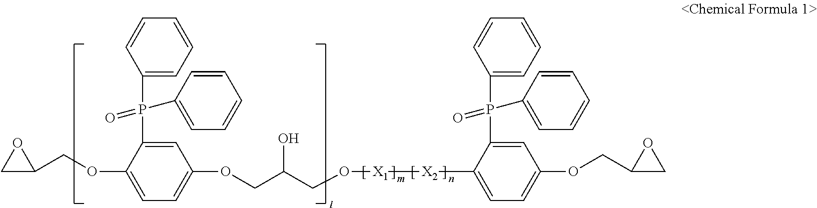

(wherein X₁ is a compound represented by Chemical Formula 11 below, X₂ is a compound represented by Chemical Formula 12 below, 1 is 1 to 2, m is 1 to 2, and n is an integer of 1 to 2.)

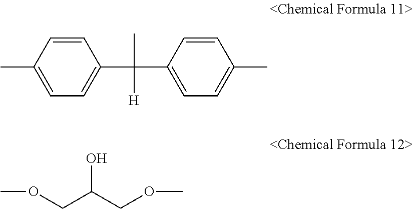

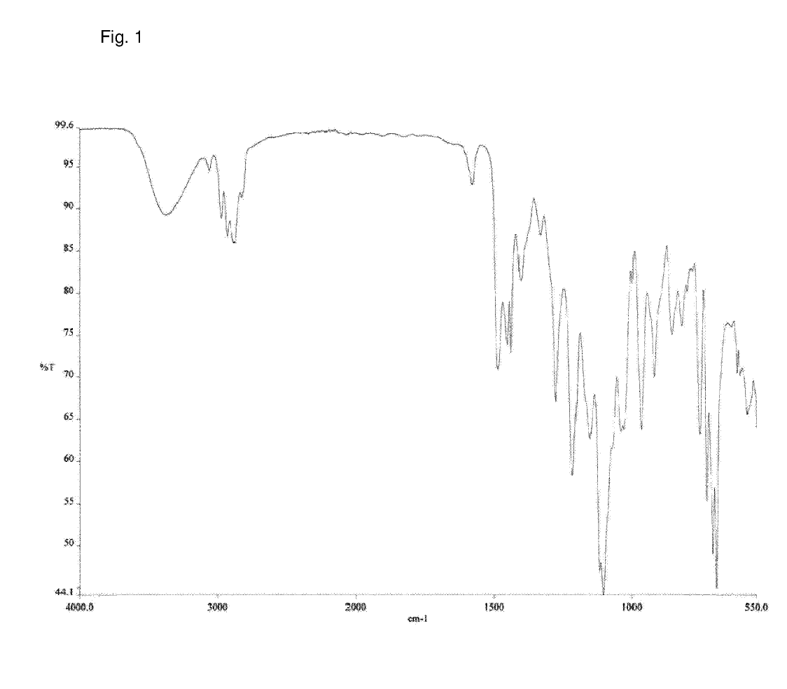

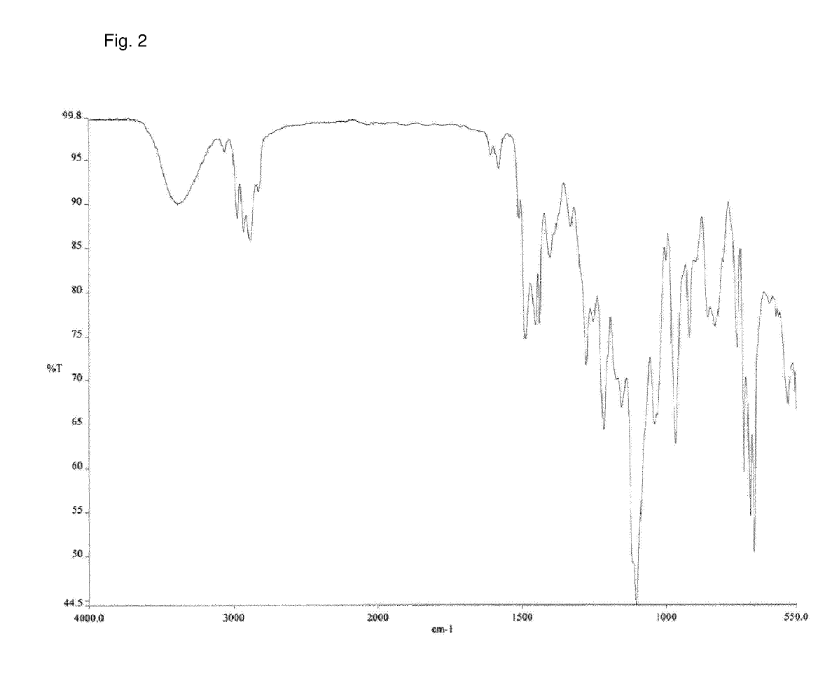

FIG. 1 is an IR graph of the compound represented by Chemical Formula 1 of Example 1 according to the present invention, and FIG. 2 is an IR graph of the compound represented by Chemical Formula 1 of Example 2 according to the present invention. The IR graphs of the compound represented by Chemical Formula 1 in Examples 3 to 10 are similar to those of FIGS. 1 and 2, and the illustration thereof is thus omitted.

### Comparative Example 1

A P-modified flame-retardant phenol novolac epoxy resin, namely KEG-H5138 (available from Kolon Industries, INC., EEW: 297.0 g/eq, P content: 2.9 mass %), was used. The structural formula thereof is represented by Chemical Formula 13 below.

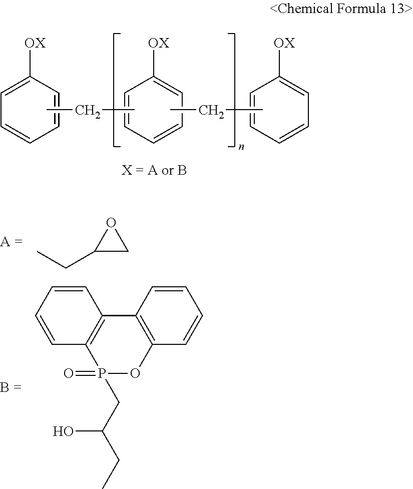

### Comparative Example 2

A P-modified flame-retardant phenol novolac epoxy resin, namely KEG-HQ5538 (available from Kolon Industries, INC., EEW: 310.0 g/eq, P content: 3.0 mass %), was used. The structural formula thereof is represented by Chemical Formula 14 below.

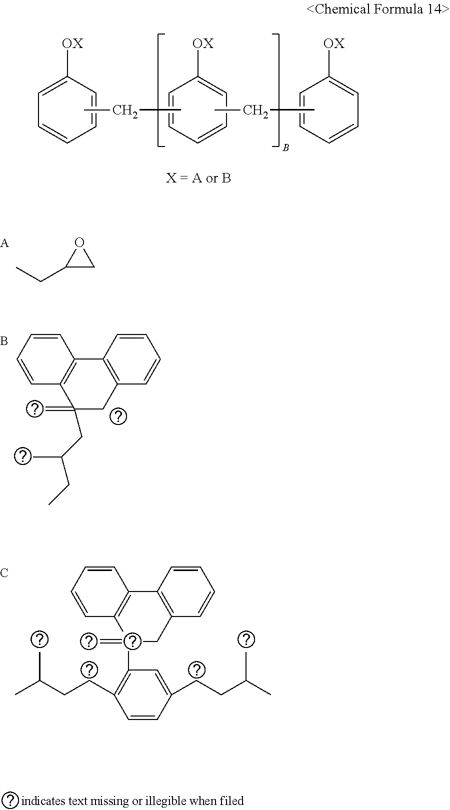

<Flame-Retardant Epoxy Resin Composition>

Individual flame-retardant epoxy resin compositions (varnish) were prepared by mixing the flame-retardant epoxy resin compounds of Examples 1 to 10 and Comparative Examples 1 and 2 in the amounts shown in Table 1 below so that the P content of the composition was adjusted to 2.5 mass %.

The preparation of the varnish was as follows.

Commonly useful as a curing agent, dicyandiamide (DICY) was employed, and in order to adjust the P content of the varnish, a phenol-modified novolac resin KEP-113P8 (available from Kolon Industries, INC., EEW: 180 g/eq) was used. The amount of DICY was added at a molar ratio suitable for the equivalent weight of the mixture comprising KEP-113P85 and the epoxy resin. A curing promoter was 2-methylimidazole (2MI), and the amount thereof was set to 500 ppm based on the total amount of added epoxy (KEP-113P85+epoxy resin (the compound represented by Chemical Formula 1 of each of Examples 1 to 10 or the compound of each of Chemical Formulas 13 and 14 of Comparative Examples 1 and 2)).

TABLE 1

| | | | | Compound of Chemical |
|---|---|---|---|---|
| | | | | Formula 1 of each of |
| | | | | Examples 1 to 10 or |
| | | | | Compound of each of |
| Mixing ratio | | | | Chemical Formulas 13 |
| of varnish | KEP- | | | and 14 of Comparative |
| (g) | 113P85 | DICY | 2MI | Examples 1 and 2 |
| Ex. 1 | 512 | 32.9 | 0.33 | 225 |
| Ex. 2 | 411 | 27.4 | 0.28 | 225 |
| Ex. 3 | 441 | 29.7 | 0.30 | 225 |
| Ex. 4 | 400 | 27.3 | 0.28 | 225 |
| Ex. 5 | 392 | 26.1 | 0.29 | 225 |
| Ex. 6 | 392 | 26.0 | 0.28 | 225 |
| Ex. 7 | 382 | 25.3 | 0.28 | 225 |
| Ex. 8 | 412 | 26.9 | 0.28 | 225 |
| Ex. 9 | 402 | 26.7 | 0.28 | 225 |
| Ex. 10 | 422 | 28.0 | 0.28 | 225 |
| C. Ex. 1 | 32 | 9.26 | 0.12 | 225 |
| C. Ex. 2 | 31 | 8.45 | 0.12 | 225 |

As is apparent from Table 1, the compound represented by Chemical Formula 1 of each of Examples 1 to 10 had high P content, and thus, upon preparation of the varnish, the amounts of the curing agent and the curing promoter could be increased. Accordingly, when the composition is prepared using the flame-retardant epoxy resin of the present invention, it is capable of containing large amounts of other components that manifest various properties, thus exhibiting the desired properties of the composition.

<Fabrication of Copper Clad Laminate>

A glass fiber was impregnated with the varnish of Table 1 and dried at 155° C. for 3 min to make a prepreg, four sheets of the prepreg thus prepared were stacked, and pieces of copper foil were stacked on the upper and lower surfaces of the prepreg stack and then pressed, thus manufacturing a copper clad laminate. (Pressing conditions: temperature of 190° C., pressure of 25 kgf/cm², processing time of 2 hr)

In the present invention, the following analysis methods were used.

1) Measurement of P Content

P content was theoretically calculated through the monomer of each structure.

2) Measurement of Glass Transition Temperature

The glass transition temperature of the copper clad laminate was measured using a differential scanning calorimeter (DSC, available from TA Instrument, Q2000). (Measurement portion: middle portion, 20 mg, measurement conditions: nitrogen atmosphere, heating to 250° C. at a heating rate of 20° C./min)

3) Measurement of weight average molecular weight: Using gel permeation chromatography (GPC, Waters: Waters707), the weight average molecular weight (Mw) was determined. The polymer to be measured was dissolved to a concentration of 40000 ppm in tetrahydrofuran and was then injected in an amount of 100 μL into GPC. The mobile phase of GPC was tetrahydrofuran, and was injected at a flow rate of 1.0 mL/min, and analysis was performed at 35° C. Four columns, namely a Waters HR-05, 1, 2, and 4E, were connected in series. Measurement was performed using a RI and PAD Detector at 35° C.

4) Measurement of Epoxy Equivalent Weight

An appropriate amount of a sample was placed in an Erlenmeyer flask with a stopper, and was completely dissolved in 10 mL of 2-methoxyethanol. After the dissolution, exactly 25 mL of 0.2 N HCl dioxane was added. The flask was covered with the stopper, dioxane was added in one or two droplets into the boundary of the flask, the flask was tightly closed, and the reaction was carried out at room temperature for 30 min. After the reaction, the flask and the stopper were washed with about 10 mL of 2-methoxyethanol and the washed solution was placed in the flask. A Cresol Red indicator was added in three droplets and titration was performed with a 0.1 N NaOH methanol solution. Simultaneously, blank testing was performed. The epoxy equivalent weight was determined using the following Equation 1, wherein W is the weight of the sample, B is the titration volume of the blank, A is the titration volume of the sample, and F is the factor value.

Epoxy equivalent weight: 10000×W/((B−A)×F) [Equation 1]

5) Measurement of Peel-Strength and Inter-Ply Adhesion

Measurement was performed using an Asida-DZC-5 available from Asida.

6) Measurement of Moisture Absorption

A test sample cut to a size of 50 mm×50 mm was dried in an oven at 50° C. for 24 hr, the dry weight thereof was measured, the test sample was stored in a bath under conditions of 85° C./85% RH for 72 hr, and the weight thereof was then measured.

7) Measurement of Flame Retardancy

Measurement was performed through the UL-94 method.

TABLE 2

| | | Flame | Peel | Inter-ply | Moisture |
|---|---|---|---|---|---|
| | | retardancy | strength | adhesion | absorption |
| | Tg | (UL-94) | (N/mm) | (N/mm) | (wt %) |
| Ex. 1 | 165.1 | V-0 | 1.48 | 1.08 | 0.57 |
| Ex. 2 | 170.1 | V-0 | 1.52 | 1.05 | 0.56 |
| Ex. 3 | 168.7 | V-0 | 1.45 | 1.02 | 0.58 |
| Ex. 4 | 169.1 | V-0 | 1.43 | 1.01 | 0.57 |
| Ex. 5 | 163.5 | V-0 | 1.42 | 1.04 | 0.60 |
| Ex. 6 | 175.4 | V-0 | 1.45 | 1.06 | 0.59 |
| Ex. 7 | 177.1 | V-0 | 1.43 | 1.02 | 0.53 |
| Ex. 8 | 168.3 | V-0 | 1.42 | 1.04 | 0.59 |
| Ex. 9 | 167.4 | V-0 | 1.42 | 1.05 | 0.59 |
| Ex. 10 | 166.1 | V-0 | 1.43 | 1.04 | 0.57 |
| C. Ex. 1 | 141.2 | V-0 | 1.38 | 0.99 | 0.68 |
| C. Ex. 2 | 149.2 | V-0 | 1.41 | 1.01 | 0.65 |

As is apparent from Table 2, in Examples 1 to 10, even when each composition having high P content was used in a small amount, it exhibited superior flame retardancy and participated in a curing reaction to thus manifest effective heat resistance and adhesion by virtue of large numbers of benzene rings and —OH groups in the resin. However, in Comparative Examples 1 and 2, the P-modified epoxy resin was contained in a large amount compared to the Examples, thus deteriorating the properties.

### INDUSTRIAL APPLICABILITY

The present invention can be useful in a flame-retardant epoxy resin, a method of preparing the same, and a flame-retardant epoxy resin composition including the same.

1. A flame-retardant epoxy resin, comprising a compound represented by Chemical Formula 1 below: 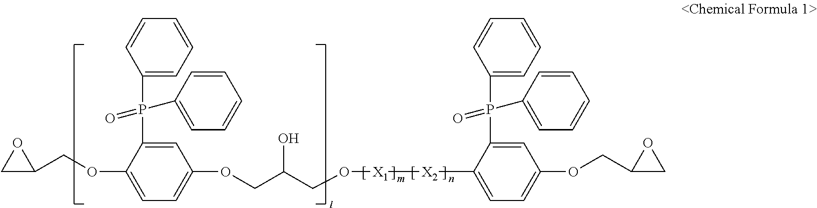
wherein X₁ is a compound represented by Chemical Formulas 2 to 11 below, X₂ is a compound represented by Chemical Formula 12 below, 1 is 1 to 10, m is 0 to 10, and n is an integer of 1 to 10,

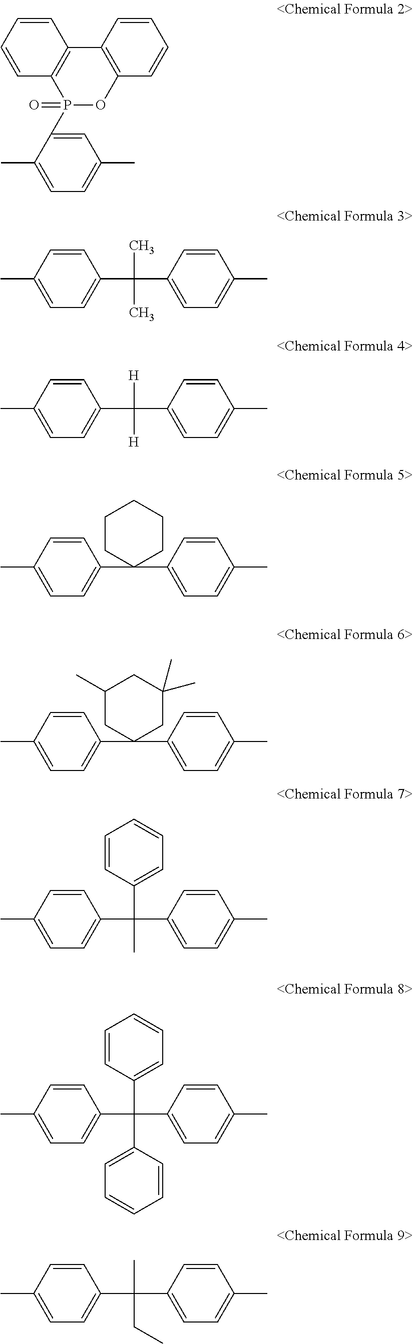

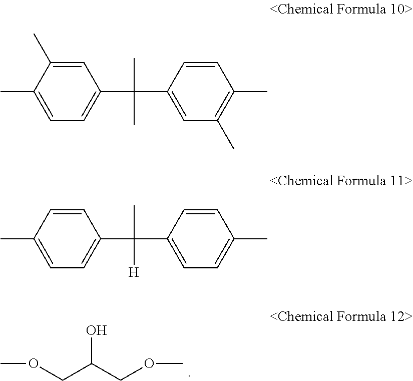

2. The flame-retardant epoxy resin of claim 1, wherein the compound represented by Chemical Formula 1 has a phosphorus content of 6 to 8 mass %.

3. The flame-retardant epoxy resin of claim 1, wherein the compound represented by Chemical Formula 1 has a glass transition temperature of 150 to 190° C.

4. The flame-retardant epoxy resin of claim 1, wherein the compound represented by Chemical Formula 1 has a weight average molecular weight of 500 to 1500 g/mol.

5. The flame-retardant epoxy resin of claim 1, wherein the compound represented by Chemical Formula 1 has an epoxy equivalent weight of 350 to 500 g/eq.

6. A method of preparing a flame-retardant epoxy resin, comprising:
(S1) preparing an intermediate compound by reacting a hydroquinone-based compound containing a phosphorus (P) atom with a halohydrin-based compound; and
(S2) reacting the intermediate compound with any one or a mixture of two or more selected from among a phosphorus-based compound and a bisphenol-based compound, and a phenyl-based compound.

7. The method of claim 6, wherein the hydroquinone-based compound containing the phosphorus (P) atom in (S1) is added at a molar ratio of 1/6 to 1/2 relative to the halohydrin-based compound.

8. The method of claim 6, wherein in (S1), after the reacting the hydroquinone-based compound containing the phosphorus (P) atom with the halohydrin-based compound, a separation process for removing an salt layer and degassing process for removing unreacted halohydrin-based compound and water at 100 to 200° C. is performed under a pressure of 100 to 760 torr.

9. The method of claim 8, wherein before the degassing process, the hydroquinone-based compound containing the phosphorus (P) atom and the halohydrin-based compound are primarily aged for 2 to 24 hr while being maintained at a temperature of 50 to 80° C. and then secondarily aged for 10 min to 4 hr while being maintained at a temperature of 50 to 100° C. under a pressure of 100 to 760 torr.

10. The method of claim 8, wherein after the degassing process, removal of a halogen ion and neutralization with an acid are performed.

11. The method of claim 6, wherein in (S1), the hydroquinone-based compound containing the phosphorus (P) atom is diphenylphosphinyl hydroquinone.

12. The method of claim 6, wherein in (S1), the halohydrin-based compound is selected from among epichlorohydrin, epiiodohydrin, epibromohydrin, methyl ethyl bromohydrin and methyl ethyl iodohydrin.

13. The method of claim 6, wherein in (S2), 100 parts by weight of the intermediate compound and 0.1 to 100 parts by weight of the any one or mixture of two or more selected from among the phosphorus-based compound and the bisphenol-based compound are reacted.

14. The method of claim 6, wherein in (S2), the phenyl-based compound that is a catalyst is added in an amount of 0.01 to 5 parts by weight based on 100 parts by weight of the any one or mixture of two or more selected from among the phosphorus-based compound and the bisphenol-based compound.

15. The method of claim 6, wherein in (S2), the phosphorus-based compound is selected from among 10-(2′,5′-dihydroxyphenyl)-9,10-dihydro-9-oxa-10-phosphaphenanthrene-10-oxide and 2-(6-oxido-6H-dibenz(c,e)(1,2)oxaphsophorin-6-yl)-1,4-naphthalenediol.

16. The method of claim 6, wherein in (S2), the bisphenol-based compound is selected from among bisphenol A, bisphenol F, bisphenol Z, bisphenol-TMC, bisphenol AP, bisphenol BP, bisphenol B, bisphenol C and bisphenol E.

17. The method of claim 6, wherein in (S2), the phenyl-based compound is selected from the group consisting of ethyltriphenylphosphonium iodide, 2-methylimidazole, 2-ethyl-4-methyl imidazole and 2-phenylimidazole.

18. A flame-retardant epoxy resin composition, comprising a compound represented by Chemical Formula 1 below, a curing agent and a curing promoter. 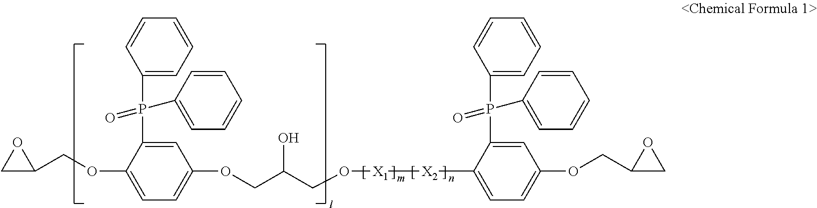
wherein X₁ is a compound represented by Chemical Formulas 2 to 11 below, X₂ is a compound represented by Chemical Formula 12 below, 1 is 1 to 10, m is 0 to 10, and n is an integer of 1 to 10,

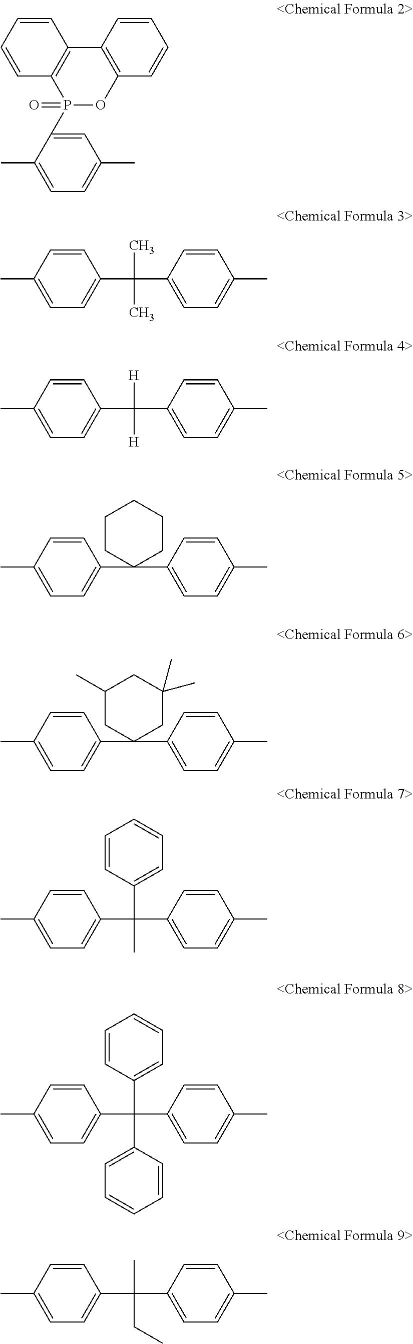

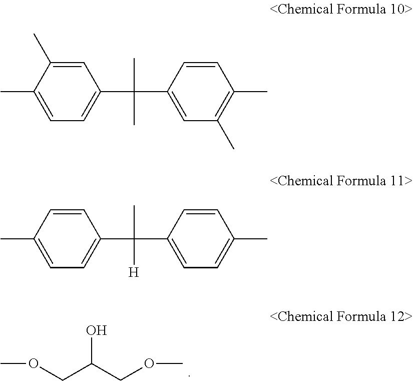

19. The flame-retardant epoxy resin composition of claim 18,
comprising 100 parts by weight of the compound represented by Chemical Formula 1, 0.1 to 50 parts by weight of the curing agent, and 0.0001 to 0.05 parts by weight of the curing promoter.

20. The flame-retardant epoxy resin composition of claim 18,
wherein the compound represented by Chemical Formula 1 is prepared by a method comprising:
(S1) preparing an intermediate compound by reacting a hydroquinone-based compound containing a phosphorus (P) atom with a halohydrin-based compound; and
(S2) reacting the intermediate compound with any one or a mixture of two or more selected from among a phosphorus-based compound and a bisphenol-based compound, and a phenyl-based compound.
